(19) United States
(12) Patent Application Publication
(10) Pub. No.: US 2006/0186438 A1
(43) Pub. Date: Aug. 24, 2006

(54) Device for thermal sensing

(75) Inventor: Katarina Verhaegen, Bertem (BE)

Correspondence Address: KNOBBE MARTENS OLSON & BEAR LLP, 2040 MAIN STREET, FOURTEENTH FLOOR, IRVINE, CA, 92614, US

(73) Assignee: VIVACTIS N.V.

(21) Appl. No.: 11/345,638

(22) Filed: Feb. 1, 2006

Related U.S. Application Data
(63) Continuation-in-part of application No. 10/967,967, filed on Oct. 19, 2004.
Application No. 10/967,967 is a continuation of application No. 10/385,410, filed on Mar. 7, 2003, now Pat. No. 6,843,596.
Application No. 10/385,410 is a continuation of application No. 10/076,750, filed on Feb. 12, 2002, now Pat. No. 6,545,334.
Application No. 10/076,750 is a continuation of application No. 08/994,176, filed on Dec. 19, 1997, now Pat. No. 6,380,605.

(51) Int. Cl. H01L 31/109

(52) U.S. Cl. 257/200

(57) ABSTRACT

The present invention provides a device for thermal sensing which uses a replaceable or disposable substrate comprising channels for receiving a sample to be measured. The device according to the invention is cost-effective as the replaceable or disposable substrate can be reused.

### RELATED APPLICATIONS

This application is a continuation-in-part application, and claims the benefit under 35 U.S.C §120 of application Ser. No. 10/967,967, filed on Oct. 19, 2004, published under US-2005/0051807 on Mar. 10, 2005, which is a continuation of application Ser. No. 10/385,410 filed on Mar. 7, 2003, now U.S. Pat. No. 6,843,596 issued Jan. 18, 2005, which is a continuation of US application entitled DEVICE AND A METHOD FOR THERMAL SENSING, application Ser. No. 10/076,750, filed Feb. 12, 2002, now U.S. Pat. No. 6,545,334, issued Apr. 8, 2003, which is a continuation of US application entitled DEVICE AND A METHOD FOR THERMAL SENSING, application Ser. No. 08/994,176, filed Dec. 19, 1997, now U.S. Pat. No. 6,380,605, issued Apr. 30, 2002, and each of which is incorporated by reference.

### FIELD OF THE INVENTION

The invention is related to a device which yields an electrical output signal but has an input or intermediate signal of the thermal type and which uses a replaceable substrate comprising channels suitable for receiving a sample to be measured. Such a device can be used to characterize chemical and physical processes which are accompanied by changes in heat content or enthalpy.

### BACKGROUND OF THE INVENTION

New approaches in the combinatorial chemistry have resulted in the capability of producing millions of compounds in a short time. Analysis of each compound with respect to multiple parameters is proving to be a significant bottleneck as in, e.g., M. A. Shoffner et al., Nucleic Acids Research, 1996, vol. 24, No. 2, pp. 375-9. The number of cells, the test reagent volumes, the throughput rate and the ease of use through automation are all important parameters which should be optimized in order to meet the stringent requirements for modern drug screening. Furthermore, a small amount of precious reagent reduces both cost and waste, and increases the number of possible analysis. A candidate for this kind of analysis is a calorimeter. A calorimeter is a device which yields an electrical output signal but has an input or intermediate signal of the thermal type. Calorimetry, more than pH-metry, offers the advantage of generality: all chemical and physical processes are accompanied by changes in heat content, or enthalpy. In fact microcalorimeters can be used for the analysis of the activity of biological cells, chemical reactions in small volumes and other microanalytical applications.

The presently most frequently used commercially available calorimeters are the Thermometric 2277 Thermal Activity Monitor and the MicroCal MCS Isothermal Titration Calorimeter. They are both based on the use of two or more thermo-electric devices, so called thermopiles, having a common heat sink as reference. A thermopile is at least one thermocouple which is a temperature sensing element and which is connected to identical thermocouples in parallel thermally and in series electrically. Thermocouples do not measure the temperature itself, but rather the temperature difference between two junctions. An advantage of using thermocouples as temperature sensing elements is that there is no offset, i.e., when there is no temperature difference there is no voltage, which makes calibration superfluous. A thermocouple as illustrated in FIG. 2, i.e., a combination of two different (semi)conductive materials, converts a thermal difference between its two junctions into a voltage difference by means of the combined Seebeck coefficient S of its two structural thermo-electric materials. In fact, a thermocouple comprises a first conductive material 14 and a second conductive material 13 with an insulating layer 15 in between. A thermocouple has a so-called hot junction 11, where the first material and the second material are short circuited, and a so-called cold junction 12, where the first and the second conductive material 14, 13 are separated one from another by means of the insulating layer 15. At the cold junction 12 the electrical output signal, representing the temperature difference ΔT between the hot junction 11 and the cold junction 12, can be measured.

The total generated voltage is the sum of the individual thermocouple voltages. For n (n being a positive whole number greater than zero) thermocouples, where each thermocouple is identical, the total generated voltage Uₜₚ can be written as:
Uₜₚ=n*S*ΔT

S is the Seebeck coefficient, and the temperature difference ΔT is the product of the generated power difference between the two junction sites and the thermal resistance:
ΔT=ΔP_{gen}*Rₜₕ
Thermopiles are preferred because they are self-generating, easy to integrate and because the temperature changes involved are low frequency signals.

The drawbacks of these state-of-the art devices are the following. These devices have at least two thermopiles and a common heat sink. The cold junctions of each thermopile are thermally coupled to the common heat sink which is at a known temperature. The hot junctions of each thermopile are thermally coupled to a substance under test. So in fact, one tries to perform a kind of absolute measurement by measuring the temperature difference between this substance under test and the heat sink at known temperature. By applying different substances under test to different thermopiles, e.g., for drug screening where the hot junctions of a first thermopile are coupled to reference cells and the hot junctions of a second thermopile are coupled to genetically engineered cells expressing a drug target. When the potential drug candidate is effective, it will activate the genetically engineered cells which results in a heat change. This heat change is determined indirectly by subtracting the measured signals of the first and the second thermopile, where the cold junctions of both thermopiles are coupled to a common heat sink at known temperature. This is a cumbersome approach which lacks accuracy and demands a space-consuming design.

### SUMMARY OF THE INVENTION

It is an object of the invention to provide an instrument or device for monitoring processes which are accompanied by changes in heat content or enthalpy, which instrument or device is cost-effective and does not suffer substantially from cross-contamination.

Although there has been constant improvement, change and evolution of devices in this field, the present concepts are believed to represent substantial new and novel improvements, including departures from prior practices, resulting in the provision of more efficient, stable and reliable devices of this nature.

The present invention provides an instrument or device for monitoring processes which are accompanied by changes in heat content or enthalpy. The instrument or device comprises:
a support having a first surface and a second surface,
at least one pair of thermally sensitive devices, wherein one device is located in a first region of the first surface of the support and the other device is located in a second region of the first surface of the support, and wherein each thermally sensitive device generates an electrical output signal in response to a thermal input,
   a replaceable substrate comprising a first channel for bringing a first substance in thermal contact with the second region, and a second channel for bringing the second substance in thermal contact with the second region, wherein the replaceable substrate is formed of a polymeric material.

The first region is thermally isolated from the second region. Preferably, the support can thermally and electrically isolate the first region and the second region. The replaceable or disposable substrate may have a thickness of between 2 μm and 3 mm and may preferably be between 70 and 100 μm.

The at least one pair of thermally sensitive devices may preferably be a thermopile.

According to embodiments of the invention, the polymeric material may form a polymeric foil or a polymeric sheet or a polymeric film. The polymeric sheet, polymeric foil or polymeric film may comprise a 3D pattern.

According to embodiments of the invention, the polymeric material may be TOPAS® Thermoplastic Olefin Polymer of Amorphous structure. However, any other suitable polymer material may also be used. With suitable polymer material is meant any polymer material that is inert with respect to the sample to be measured, does not allow diffusion of at least part of the sample to be measured through the polymeric sheet or foil or film, is inert to the measurement or thermal sensing device and is thermally isolating.

According to some embodiments of the invention, the instrument or device may furthermore comprise an amount of thermally conductive material, preferably thermally conductive fluid such as oil or oil-like material or thermally conductive paste, present at a side of the replaceable substrate, e.g. polymer foil or polymer sheet or polymer film, facing the at least one pair of devices, e.g. thermopile. In that way, the thermal contact between the replaceable substrate, e.g. polymer foil, and the at least one pair of thermally sensitive devices, e.g. thermopile, may be increased.

According to embodiments of the invention, the first and second channel may have a bottom and the bottom of the first and second channel may comprise a reservoir for being provided with a drop of thermally conductive material, preferably thermally conductive fluid such as oil or oil-like material or thermally conductive paste. The drop of thermally conductive material, e.g. oil, oil-like material or thermally conductive paste, may then be sucked toward edges of the channels by means of capillary forces when the replaceable substrate, e.g. polymer foil or polymer sheet or polymer film, is placed upon the underlying support substrate, membrane or support plate. In that way, a good thermal path between the replaceable substrate, e.g. polymer foil or polymer sheet or polymer film, and the thermally sensitive devices, e.g. thermopile, may be obtained.

According to embodiments of the invention, the amount of thermally conductive material, preferably thermally conductive fluid such as oil or oil-like material or thermally conductive paste, may be between 10 nl and 10 μl.

According to some embodiments of the invention, the replaceable substrate, e.g. polymer foil or polymer sheet or polymer film, may comprise a side facing the at least one pair of devices, e.g. thermopile, and the side of the replaceable substrate facing the at least one pair of devices, e.g. thermopile, may chemically be modified so as to be hydrophilic. By doing so a drop of thermally conductive material, such as e.g. oil or oil-like material, in between the replaceable substrate and the support will stay on the support upon removal of the replaceable substrate, e.g. polymer foil or polymer sheet or polymer film, after an experiment or measurement is finished and thus, the thermally conductive material such as e.g. oil or oil-like material has only to be provided once and does not have to be provided before every experiment.

The instrument or device may, according to some embodiments of the present invention, furthermore comprise a take-up roll and a dispensing roll for providing a continuous system of providing and removing parts of replaceable substrate, e.g. polymer foil or polymer sheet or polymer film. In that way, the replaceable substrate may be provided above the thermal sensing device by means of the dispensing roll and, after a measurement, can be removed from above the thermal sensing device by rolling it on a take-up roll.

According to embodiments of the invention, the replaceable substrate, e.g. polymer foil or polymer sheet or polymer film, may comprise a surface that, in use, is in contact with a sample to be measured and wherein that surface is modified so as to provide pre-determined binding characteristics.

The present invention furthermore discloses the use of the instrument or device according to the invention in calorimetric screening.

Furthermore, the present invention discloses the use of the instrument or device according to the invention in analysis of activity of biological cells.

Other features and advantages of the present invention will become apparent from the following detailed description, taken in conjunction with the accompanying drawings, which illustrate, by way of example, the principles of the invention.

These and other objects and features of the present invention will become better understood through a consideration of the following description taken in conjunction with the drawings.

### BRIEF DESCRIPTION OF THE DRAWINGS

FIG. 1 depicts two schematic representations of a thermal sensing device according to two different embodiments of the present invention.

FIG. 2 depicts a schematic representation of a thermocouple, the thermocouple being part of a thermopile as may be used in embodiments of the present invention.

FIG. 3 depicts a schematic flow of a method for fabricating a thermal sensing device as can be used with embodiments of the present invention.

FIG. 4 depicts a schematic flow of a method for fabricating a rubber membrane, i.e., a membrane composed of ELASTOSIL LR3003/10A, B (Wacker Chemie), as can be used with embodiments of the present invention.

FIG. 5 depicts a schematic flow of a method for fabricating a thermal sensing device as can be used with embodiments of the present invention.

FIGS. 6 and 7 illustrate a device according to embodiments of the present invention, showing different supports for a replaceable substrate.

FIG. 8 illustrates a device according to a further embodiment of the invention, where thermally conductive material such as oil is used to increase thermal contact between the foil of the replaceable substrate and the sensor.

FIGS. 9A and 9B illustrate a thermal sensing device according to an embodiment of the invention.

FIG. 10 illustrates provision of a sample to a thermal sensing device according to an embodiment of the present invention.

FIGS. 11A and 11B illustrate the use of a thermal sensing device according to an embodiment of the invention for 1-1 reactions.

FIG. 12 illustrates a device according to a further embodiment of the present invention. FIG. 13A illustrates a support which can be used according to embodiments of the present invention.

FIG. 13B shows a cross-section of the support of FIG. 13A in combination with a replaceable substrate according to embodiments of the present invention.

In the different figures, the same reference signs refer to the same or analogous elements.

### DESCRIPTION OF THE PREFERRED EMBODIMENTS

In relation to the appended drawings, various embodiments of the invention are described in detail below. It is apparent however that a person skilled in the art can envision other embodiments or other ways of practising the present invention, the spirit and scope thereof being limited only by the terms of the appended claims. The drawings described are only schematic and are non-limiting. In the drawings, the size of some of the elements may be exaggerated and not drawn on scale for illustrative purposes. Where the term “comprising” is used in the present description and claims, it does not exclude other elements or steps.

Furthermore, the terms first, second, third and the like in the description and in the claims, are used for distinguishing between similar elements and not necessarily for describing a sequential or chronological order. It is to be understood that the terms so used are interchangeable under appropriate circumstances and that the embodiments of the invention described herein are capable of operation in other sequences than described or illustrated herein.

A device is disclosed yielding an electrical output signal but having an input or intermediate signal of the thermal type. The device can be used, e.g., for the analysis of the activity of biological cells, chemical reactions in small volumes and other microanalytical applications. Particularly the device can be used to monitor chemical and physical processes which are accompanied by changes in heat content or enthalpy. Furthermore the device can be used to thermodynamically characterize a biological interaction as a means to rational drug design, to drug stability and drug effect studies on cells and blood. In the further description, for the ease of explanation, the device yielding an electrical output signal but having an input or intermediate signal of the thermal type will be referred to as device or as thermal sensing device.

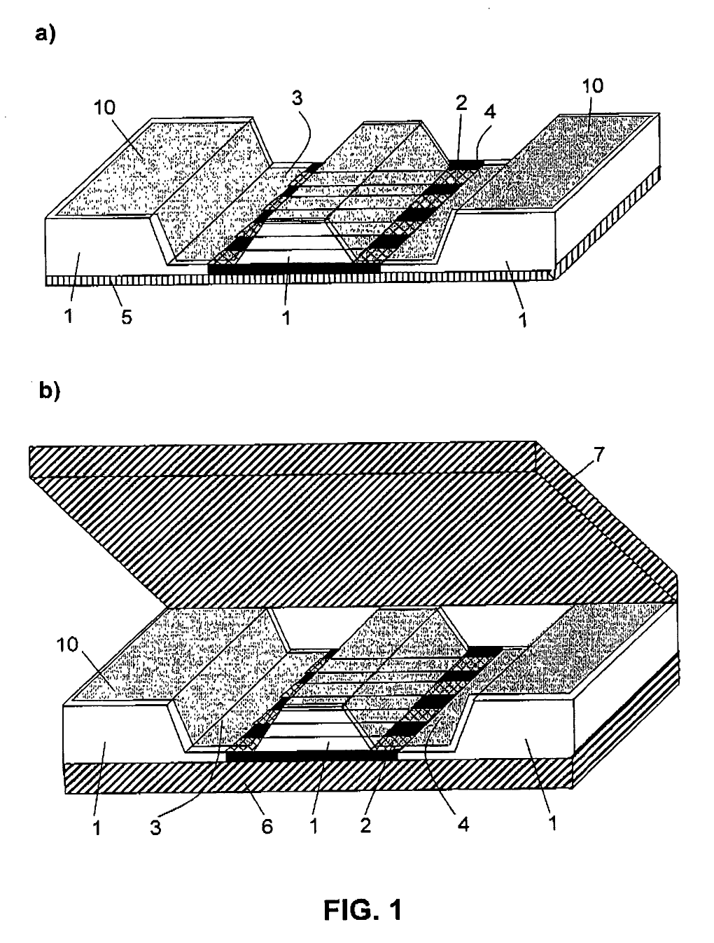

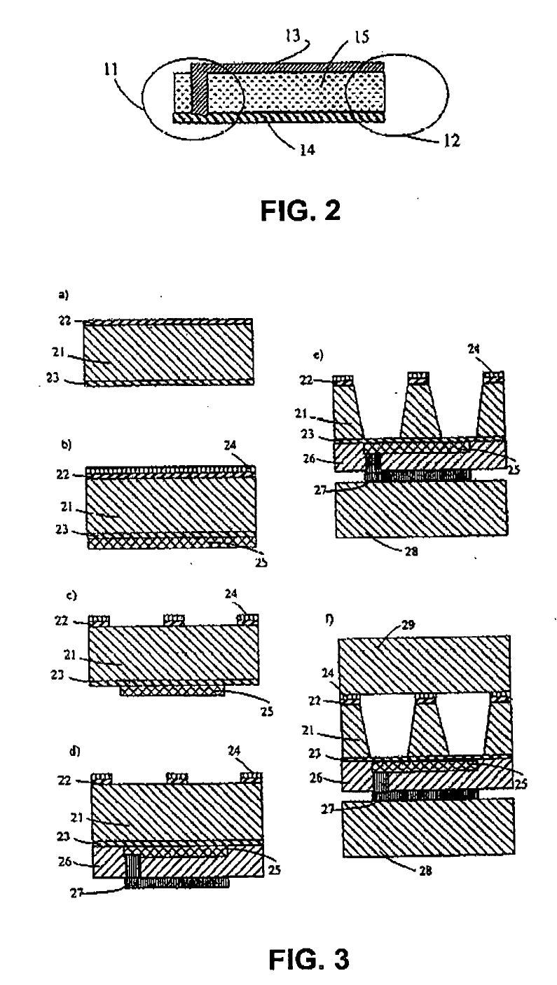

In an embodiment of the invention a device, as in FIG. 1, embodiments a) or b), for monitoring chemical and physical processes which are accompanied by changes in heat content or enthalpy is disclosed, comprising a thermopile 2, wherein the thermopile 2 is in contact with a part of a substrate or support 1, e.g., a silicon wafer or the remains thereof, and wherein the thermopile 2 is at least one thermocouple (FIG. 2) comprising a first conductive material 14 and a second conductive material 13 with an insulating layer 15 in between. The first and the second conductive materials 14, 13 are chosen such that their thermoelectric voltages are different. The choice of the conductive materials is further based on several parameters as there are the magnitude of their Seebeck coefficient, their electrical resistivity, their availability and their compatibility with standard processing steps as used in the manufacturing of integrated circuits. An increase in Seebeck coefficient corresponds with an increase in sensitivity while a lower resistivity corresponds with a lower noise level and thus an improved signal to noise ratio. Each thermocouple has a so-called hot junction 11, where the first conductive material 14 and the second conductive material 13 are short-circuited, and a so-called cold junction 12, where the first material 14 and the second material 13 are separated one from another by means of the insulating layer 15. At the cold junction 12 the electrical output signal, representing the temperature difference between the hot junction 11 and the cold junction 12 of the same thermopile 2, can be measured. Preferably the thermocouples of the thermopile 2 are connected in parallel thermally and in series electrically. By doing so, the hot junctions 11 as well as the cold junctions 12 of the different thermocouples of the same thermopile 2 are grouped.

A first substance, i.e., a reference substance, can be thermally coupled to the cold junctions 12 of the thermopile 2 while a second substance, i.e., a test substance, can be thermally coupled to the hot junctions 11 of the same thermopile 2. Alternatively, a first substance, i.e., a test substance, can be thermally coupled to the cold junctions 12 of the thermopile 2 while a second substance, i.e., a reference substance, can be thermally coupled to the hot junctions 11 of the same thermopile 2. The first substance and the second substance can be brought in direct contact with the cold junctions 12 and the hot junctions 11 respectively using supply means, whereby the first substance is isolated from the second substance. Alternatively, the device can further comprise a first and a second channel 3, 4 on the thermopile 2, a first channel 3 in close vicinity of the cold junctions 12 and a second channel 4 in close vicinity of the hot junctions 11, the first channel 3 and the second channel 4 being separated and isolated one from another. The channels 3, 4 can be used to supply the substances, e.g., solutions, to the junctions 11, 12. It has to be noted that the channels 3, 4 do not necessarily have to be formed in the substrate or support 1 (see further).

According to the present invention, the first and second channel 3, 4 are defined in a replaceable substrate 10 (see FIGS. 1 a) and b)), which is formed of a polymeric material. Preferably, the polymeric material may be a polymeric sheet or foil or film which is formed of TOPAS® Thermoplastic Olefin Polymer of Amorphous structure (COC) obtainable from Ticona Grade 8007 (F-04). However, any other suitable polymer material may be used. With suitable polymer material is meant any polymer material that is preferably inert with respect to the sample to be measured, preferably does not allow diffusion of at least part of the sample to be measured through the polymeric sheet or foil or film used as the replaceable substrate 10, preferably does not show any kind of reaction with the measurement or thermal sensing device and is electrically and/or thermally isolating.

In the further description, the replaceable or disposable substrate 10 will further be referred to as foil 10. This, however, is not intended to put any limitations on the thickness of the substrate, which must be thin enough to transmit heat from the sample to be measured to the sensor device and should reduce the thermal path in all other directions, i.e. in the directions away from the sensor device, the usable thickness being dependent on the heat conductivity of the material used. The replaceable or disposable substrate 10 may have a thickness of between 2 μm and 3 mm and may preferably be between 70 and 100 μm.

The foil 10 can be formed into a 3D pattern by e.g. temperature elevated film post-extrusion with a mould made of e.g. hardened steel and finished with spark erosion.

The device further comprises a membrane 5 to isolate and mechanically support the thermopile 2. The membrane 5 should thermally and electrically isolate the thermopile 2 and mechanically support the thermopile 2. Silicon oxide and/or silicon nitride can be used as membrane materials. Particularly a liquid rubber, i.e., ELASTOSIL LR3003/10A, B can be used as a membrane material. The rubber membrane 5 fulfils the stringent biocompatibility requirements necessary for medical applications, allows for relatively large pressures to be built up, e.g., when the substance is a solution which is pumped through the device, renders the sensor excellent thermal isolation properties, enables the active area to be very large and makes it possible to have optical access thanks to its transparency. Alternatively, instead of a membrane 5 an insulating support plate 6, e.g., a glass plate or a polyvinylchloride (PVC-C) plate can be used.

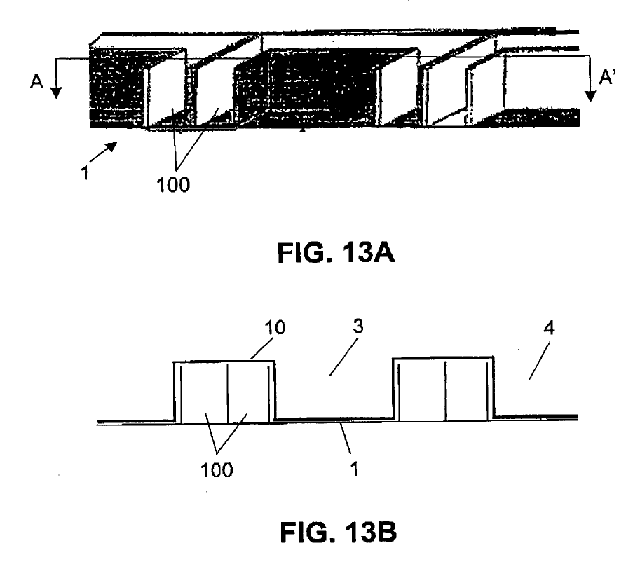

In the embodiments illustrated in FIGS. 1 a) and b), the foil 10 may be positioned on the substrate or support 1 and at least partly on the thermal sensor, e.g. thermopile 2, so as to provide an inert surface onto which a sample to be measured may be deposited. A hydrostatic or electrostatic attraction may be present between the support 1 and the replaceable substrate 10. The support 1 may be positioned on the membrane 5 (as in FIG. 1 a)) or on the support plate 6 (as in FIG. 1 b)). In these embodiments, the substrate or support 1 and the foil or replaceable substrate 10 have a same pattern, i.e. show the same channels. According to other embodiments of the invention, the support may be as shown in FIGS. 1 a) and b), but may furthermore comprise isolation zones 100 around the channels. This is illustrated in FIGS. 13A and 13B. The replaceable substrate 10 may have the same or an analogous shape as the one illustrated in FIGS. 1 a) and b). When the replaceable substrate 10 is positioned onto the support 1 it overlaps the isolation zones 100 of the support 1 as is illustrated in FIG. 13B, which is a cross-section along line AA′ of the support 1 illustrated in FIG. 13A in combination with a replaceable substrate 10 according to the present invention. The construction of the support 1 as illustrated in FIG. 13A and 13B prevents the processes in both channels 3 and 4 of the replaceable substrate 10 from influencing each other, e.g. the temperature in one channel 3 is preferably not influenced by the temperature in the second channel 4.

To speed up measurement time or to test a number of substances at the same time, a modular system comprising an array of devices, each device comprising one thermopile 2, can be configured on the same substrate.

According to one embodiment of the invention, an example of a device (FIG. 1, b)) is disclosed based on only one thermopile 2 wherein the thermopile 2 is in contact with a part of a substrate 1, e.g., a silicon wafer or the remains thereof. The cold junctions 12 of the thermopile 2 are coupled thermally to a first channel 3 comprising a first substance while the hot junctions 11 of the thermopile 2 are coupled thermally to a second channel 4 comprising a second substance, the first and the second channel 3, 4 are separated and thermally isolated one from another. The device further comprises a polyvinylchloride (PVC-C) support plate 6 at the bottom side and a similar plate 7 is used for covering the channels 3, 4 on the top side. The classical heat sink is omitted thereby fully exploiting the inherent benefits of a differential measurement using thermocouples as temperature sensing elements and resulting in a reduction in overall dimensions. Less area is consumed and the dead volume of the feeding fluid channels is reduced. The device is capable of handling a very small amount of a substance, typically in the range from 1 microliter to 30 microliter. When used, e.g., for drug screening, reference cells forming a first substance, are adhered in the first channel, while in the second channel genetically engineered cells expressing a drug target are cultivated. When the potential drug candidate is effective, it will activate the genetically engineered cells, which form the second substance, and these will cause a heat change at one side of the thermopile 2, i.e., the hot junctions 11, thereby producing a differential voltage (heat conduction type calorimeter). The reference sample is thus substantially equal to the test sample except that it cannot produce a temperature change due to physiological activation. Consequently heat capacities and surface relationships are equal. The device as such has a very high common mode rejection ratio, offering a signal which is originating only from the potential drug candidate stimulating or suppressing the metabolism of the cells under study. To handle living cells and sticky reagents, materials where the device is composed of and which are in contact with the cells, need to be fully biocompatible and sterilisable.

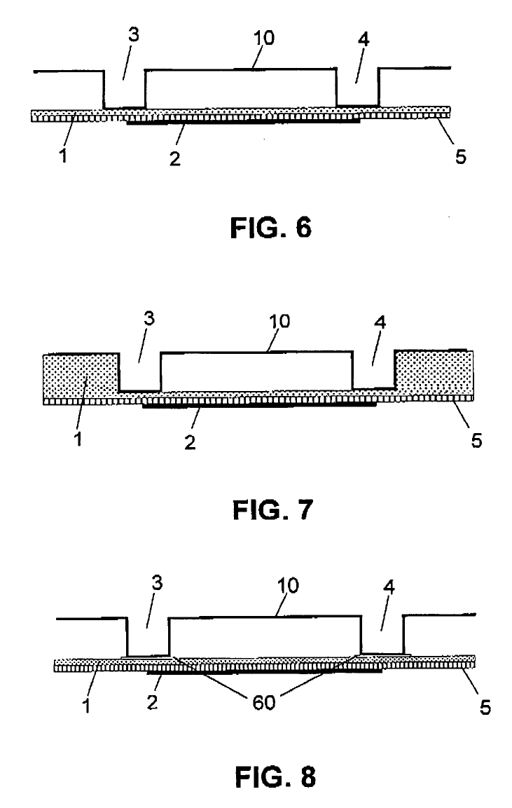

In other embodiments of the present invention, the substrate or support 1 may have other shapes than illustrated in FIGS. 1a and 1b. This is illustrated in FIG. 6 and FIG. 7. The substrate or support 1 may be formed of a layer of suitable material which is not patterned (see FIG. 6). In other embodiments, the layer of suitable material to form a support or substrate 1 may be patterned as illustrated in FIG. 7, i.e. the substrate is patterned so as to not support the foil 10 in between neighbouring channels 3, 4 above a same thermocouple, but to support the foil 10 outside those channels 3, 4. Note that these examples of FIG. 6 and FIG. 7 are not limiting the invention.

As can be seen from these FIGS. 6 and 7, the thermal sensor, e.g. thermopile 2, may also be positioned under a membrane 5, which may be positioned under the support 1 as in FIG. 1a). In FIG. 1a), the thermopile 2 was positioned above the membrane 5.

The foil 10 can be used as a disposable substrate. This means that, before a measurement is performed with the thermal sensing device, the foil 10 may first be provided with samples and may then be provided on the thermal sensing device and then the measurement can be performed. According to other embodiments of the invention, the foil 10 may first be provided on the thermal sensing device and may then be provided with samples. After the measurement, the disposable substrate 10 can be removed and another disposable substrate 10 provided or to be provided with samples can be provided for performing another measurement. In this case, the foil 10 can be strengthened by means of rims in e.g. plastic or frames that are compatible with present day automation tools, e.g. microplates.

In other embodiments according to the present invention, as illustrated in FIG. 12, the foil 10 can be provided above the thermal sensing device by means of a dispensing roll 70 and, after a measurement, can be removed from above the thermal sensing device by rolling it on a take-up roll 80. After a measurement is performed, the foil 10 is driven in a direction as indicated by arrow 90 in FIG. 12 by a driving means (not shown in the figure). In that way, the foil 10 is rolled onto the take-up roll 80 and rolled off of the dispensing roll 70, hence removing the used part of the foil 10 away from the thermal sensor, e.g. thermopile 2, and providing a clean part of foil 10 at the position of the thermal sensor, e.g. thermopile 2. The used foil 10 that is collected on the take-up roll 80 may then be removed from the take-up roll 80, e.g. after cutting, and thrown away.

The side of the foil 10 which is intended to be in contact with a sample to be measured may be modified. For example, the foil 10 can be custom coated on its surface in contact with the sample to be measured, e.g. biological sample. The coating can be e.g. PEG (poly ethylene glycol) derived to achieve maximum resistance to non-specific binding with respect to analytes present in the sample to be measured, or a dedicated coating very specific for a particular application, e.g. a protein binding layer. The foil 10 can furthermore be coated with cell adhesion promoters. Usually chemical modification may be preceded by e.g. a plasma treatment, in order to roughen up the surface of the foil 10. The foil 10 can also at least partly be laminated by a good thermal conductor at the bottom of the well to achieve a certain level of temperature uniformity across the well.

According to embodiments of the invention, a means may be provided for increasing thermal contact between the polymer foil 10 and the thermal sensor, e.g. thermopile 2. According to one embodiment of the invention which is illustrated in FIG. 8, the means for increasing thermal contact may be provided by providing a small amount of thermally conductive material, preferably thermally conductive fluid such as oil or an oil-like material 60 or thermally conductive paste between the foil 10 and the underlaying layers, such as substrate 1 and/or membrane 5 or support plate 6. The amount of thermally conductive material, e.g. oil or oil-like material 60, that may be provided is dependent upon the volume of the sample to be measured. However, it is best to keep the amount of thermally conductive material, e.g. oil or oil-like material 60, as low as possible in order to minimise the thermal inertia of the measurement. The amount of thermally conductive material, e.g. oil or oil-like material 60, may preferably be between 10 nl and 10 μl. It has to be kept in mind that certain grades of thermally conductive material, such as paste or fluid e.g. oil or oil-like material 60, can attack the material of the foil 10. Therefore, the thermally conductive material, such as paste or fluid e.g. oil or oil-like material 60, may best be provided just before the measurement is started or a thermally conductive material, such as paste or fluid, e.g. an oil or oil-like material 60, may be used which is chemically inert and thus will not attack the material of the polymer foil 10.

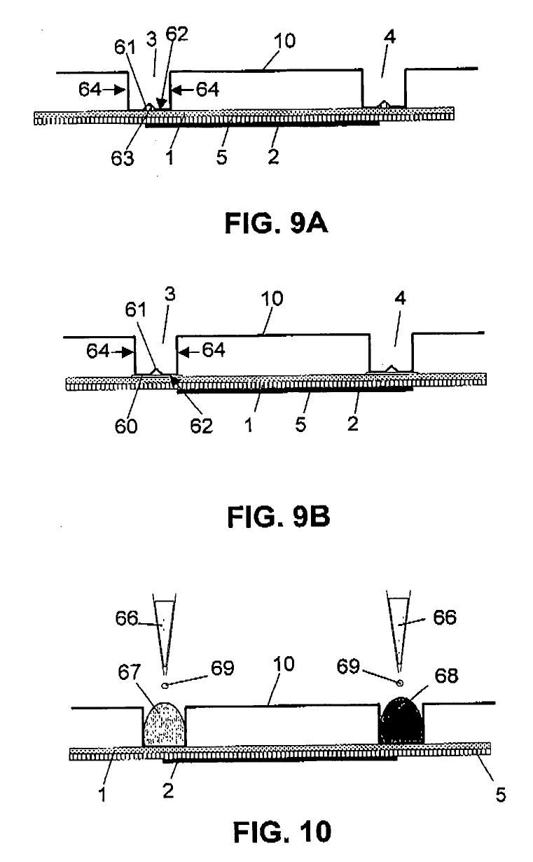

According to embodiments of the invention, as illustrated in FIG. 9A, a small reservoir 61 may be patterned at the bottom 62 of the channels 3, 4 of the foil 10. These small reservoirs 61 may be suitable to receive a drop 63 of thermally conductive material, preferably thermally conductive fluid such as oil or oil-like material or thermally conductive paste. The drop 63 of thermally conductive material may then be sucked toward the edges 64 of the channels 3, 4 by means of capillary forces when the foil 10 is placed upon the underlying support substrate 1, membrane 5 or support plate 6, as illustrated in FIG. 9B. In that way, a good thermal path between the foil 10 and the thermal sensing device may be obtained.

The foil 10, which may be intrinsically hydrophobic, can be locally chemically modified to achieve hydrophilic patches. If this is done on that side of a bottom side 62 of the channel 3, 4 which is facing the support 1, the drop 63 of thermally conductive material, e.g. oil or oil-like material, will stay on the support 1 upon removal of the foil 10 after an experiment or measurement is finished and thus, the thermally conductive material, e.g. oil or oil-like material 60, has only to be provided once and does not have to be provided between every experiment.

In that view the support 1 may be chemically modified to have a more hydrophobic character so as to achieve better adhesion of the drop 63 of thermally conductive material, e.g. oil or oil-like material 60, to the support 1.

According to other embodiments of the invention, an increase of the thermal contact between the foil 10 and the thermal sensing device can be obtained by chemical modification of that side of the foil 10 that is facing the thermal sensing device. For example, the side of the foil 10 that is facing the thermal sensing device may be electrostatically charged to increase attraction between the thermal sensing device and the foil 10. The level of attraction should be such that the foil 10 may easily be peeled of so as to be removed from the thermal sensing device after performance of the measurement, without damaging the thermal sensing device.

The sample to be measured can be provided into the channels 3, 4 formed in the foil 10 by means of, for example, a dispenser 66.

The thermal sensing device according to the present invention can be used for determining whether interaction occurs within the channels 3, 4 of the foil 10 when two samples are brought together to react. An example is illustrated in FIG. 10. A first sample 67 may be provided by means of e.g. a dispenser 66 in the first channel 3. In the second channel 4, a reference sample 68 may be provided, also by means of e.g. a dispenser 66. In a next step a second sample 69 may be provided to the first and second channel 3, 4 by means of e.g. a dispenser 66 (see FIG. 10). Reaction can occur between the first sample 67 and the second sample 69 and between the reference sample 68 and the second sample 69 in channels 3 and 4 respectively. Changes in heat resulting from the reaction between the different samples can then be measured by means of the thermal sensor, e.g. thermopile 2. Instead of performing this experiment in one channel 3, 4, as illustrated in FIG. 10, the measurement can be repeated with different concentrations in different channels 3, 4. In that way, the cost of the thermal sensing device can be reduced and cross-contamination can be minimised.

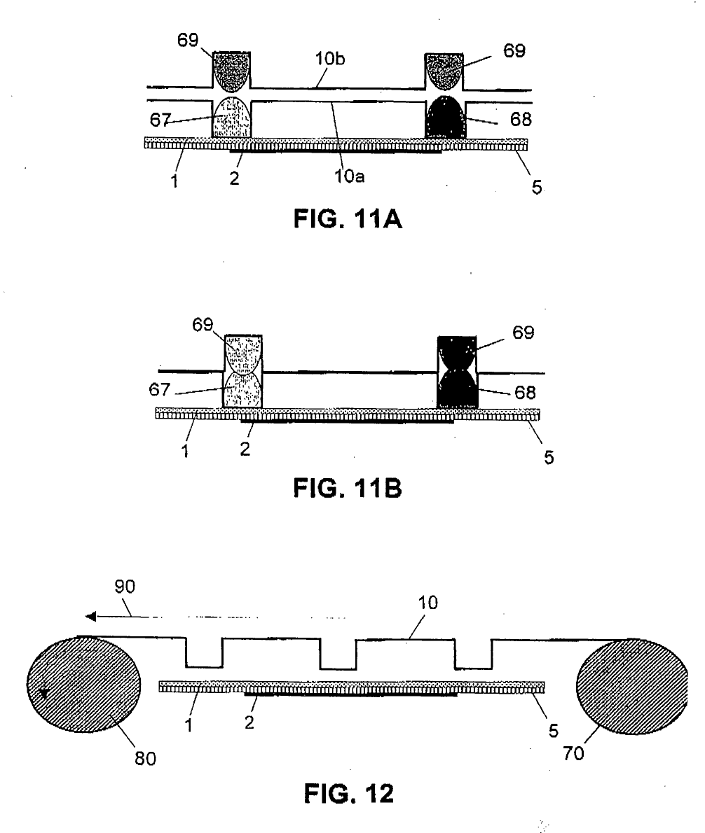

In a further embodiment, as illustrated in FIG. 11A and FIG. 11B, a first foil 10a may comprise a first sample 67 in the first channel 3 and a reference sample 68 in the second channel 4. A second foil 10b may comprise a second sample 69 in its first and second channels 3, 4. The foils 10a and 10b may be brought in proximity with respect to each other, an open side of the foils 10a and 10b facing each other so that, after reaching a thermal equilibrium between the first sample 67 and the second sample 69, the second samples 69 can be brought into physical contact with the first sample 67 and the reference sample 68 and thus can be mixed with the first sample 67 and the reference sample 68, respectively. Changes in heat resulting from the reaction between the different samples can then be measured by means of the thermal sensor, e.g. thermopile 2. By working this way, the sample recipient can be closed off such that evaporation of the samples can be minimised and other thermal disturbance coming from the environment can be reduced.

It should be noted that, according to embodiments of the present invention, the foil 10 can be filled before providing it to the thermal sensing device. The filling stage can thus be separated from the measurement stage, which is good considering optimal thermal stabilisation times. Alternatively, the filling of the channels 3, 4 of the foil 10 can be performed after the foil 10 is provided onto the thermal sensing device.

An example of a method is disclosed for fabricating a device used to monitor chemical and physical processes which are accompanied by changes in heat content or enthalpy, which device can be used in embodiments of the present invention. The device is capable of handling a very small amount of a substance. These requirements can be achieved by micromachining, a technique closely related to integrated circuit fabrication technology. The starting material is a substrate or support 21, e.g., a semiconductor wafer, particularly a monocrystalline silicon wafer, or a slice of an insulating material, i.e., a glass slice. On this substrate layers can be coated, patterned by means of a sequence of lithographic steps and wet and/or dry etching steps. Such processed substrates can be bonded to each other or to other materials in order to make three-dimensional structures. A possible implementation of such a method or process is described below as an example without limiting the scope of the invention. The materials, dimensions and process steps mentioned in this example can be easily exchanged with equivalents or equivalent steps.

The process illustrated (FIG. 3) starts with the deposition of an oxide layer 22, 23 (FIG. 3, step a)) with a thickness of 470 nm on a first and a second side of the substrate 21, e.g. a monocrystalline silicon wafer. On an unpolished side, e.g. the first side, a nitride layer 24 with a thickness of 150 nm is deposited (FIG. 3, step b)) while on the other side, e.g. the second side, a first conductive layer 25, e.g. a p-type doped polysilicon layer with a thickness of about 1 μm is deposited. The oxide layer 23 on the second side of the substrate 21 is provided as an etch stop layer for a back etch, as a layer which inhibits a direct contact of a substance to a thermopile 2 and to thermally and electrically isolate the first conductive layer 25, being part of a thermopile 2.

On the first side of the substrate 21 the nitride/oxide stack may be patterned (FIG. 3, step c)) in order to define the etch windows for etching away the underlying silicon to form twin channels. It has to be understood that, according to the present invention, this is not always required. The substrate or support 21 may be formed by a layer of suitable material, as described above, to form the substrate or support 21, without this layer being patterned to form the channels. According to the invention, the layers are defined in the replaceable substrate and hence, channels may be defined, but are not necessarily defined in the substrate 21. On the second side of the substrate 21 the p-type doped polysilicon layer 25 is patterned (FIG. 3, step c)) to thereby form the first material 13 of the thermopile 2, i.e., a set of thermocouples which are connected in parallel thermally and in series electrically.

On the second side of the substrate 21 an insulating layer 26 is deposited (FIG. 3, step d)) which is used as an inter-conductive layer dielectric and which isolates the different fingers of the polysilicon pattern. The insulating layer 26 is patterned to thereby form via holes through which the underlying polysilicon layer 26 can be contacted in order to form hot junctions 11. A second conductive layer 27, having a thermoelectric voltage different from the thermo-electric voltage of the first conductive layer 25, e.g. an aluminum layer with a thickness of e.g. 200 nm, is deposited e.g. by means of evaporation on the second side of the substrate 21. The second conductive layer 27 is patterned to thereby form the second material 14 of the thermopile 2. Aluminum and p-type polysilicon can be used to fabricate the thermopile 2 because they are standard materials and their Seebeck coefficient is large. The dielectric layer 26 between the conductive layers 25, 27 of the thermopile 2 may be a photosensitive resin derived from B-staged bisbenzocyclobutene (BCB) monomers.

The substrate 21 is diced and the second side of the substrate 21 is attached to, e.g. glued on a support plate, e.g. a polyvinylchloride (PVC-C) support plate 28 before the back etch is done in KOH (FIG. 3, step e)). A similar plate 29 is used for closing (FIG. 3, step f) the channels 3, 4 on the top side.

Instead of the support plate 28 a membrane can be introduced in devices, which are used to monitor chemical and physical processes which are accompanied by changes in heat content or enthalpy and which comprise at least one thermopile 2, to thermally and electrically isolate the thermopile 2 and to mechanically support the thermopile 2. When membranes larger than a few square centimeters need to be fabricated, conventional micromachining techniques have limitations. The materials where conventional membranes are composed of, e.g., silicon oxide and/or silicon nitride. Due to residual stress in these silicon oxide and/or silicon nitride layer(s) which form the membrane, they easily bend, crack or even break. Therefore several polymers, particularly silicone rubber, have been investigated to make flexible large area membranes. The silicone rubber used is the two-component liquid silicone rubber ELASTOSIL LR3003/10A, B (Wacker Chemie). This rubber has a high mechanical strength, i.e., a tensile strength of about 2.5 MPa, a superior elongation at break of about 620%, a perfect biocompatibility, a low thermal conductivity of about 0.2 W/mK, a high electrical resistivity of about 5.10<15>[Omega]cm, a low water uptake, a high gas permeability and a relatively low viscosity. The latter property makes a spin coating technique feasible.

The biocompatibility, high mechanical strength, high degree of transparency and low thermal conductivity of this silicone rubber invite to many application domains where conventional micromachining techniques fail. This silicone rubber can be introduced as a membrane in sensing devices comprising a thermopile 2. Transferring a thermopile 2 to a rubber membrane renders excellent thermal isolation properties to the thermopile 2 as the thermal conductance of the rubber is very small (0.2 W/mK) and the membrane can be made very thin (m range). Moreover, it offers the possibility to prepare a large size thermopile which is needed if good thermal isolation and high sensitivity are desired. Large areas are also needed if the metabolism of biological cells is being tested as cells are preferably tested in monolayers and a large number of them are needed to get a significant signal (power production of a single cell is in the order of picoWatts). Furthermore the rubber membrane fulfils the stringent biocompatibility requirements, which makes it suited for medical applications, and can sustain relatively large pressures. The use of this silicone rubber is not limited to its function as a membrane in sensing devices comprising a thermopile. Due to its high thermal resistivity, this rubber can be used to thermally isolate at least parts of all kinds of sensing devices. Due to its mechanical strength and elasticity this rubber can be used in all kind of sensing devices which benefit from these properties, e.g., flow sensing devices and actuators. Due to its low viscosity this rubber can be introduced in sensing devices by means of a spin coating technique for protection, sealing and packaging purposes. Furthermore, the transparency of the rubber opens the field for applications where optical access is needed, e.g., microscopic analyzing techniques.

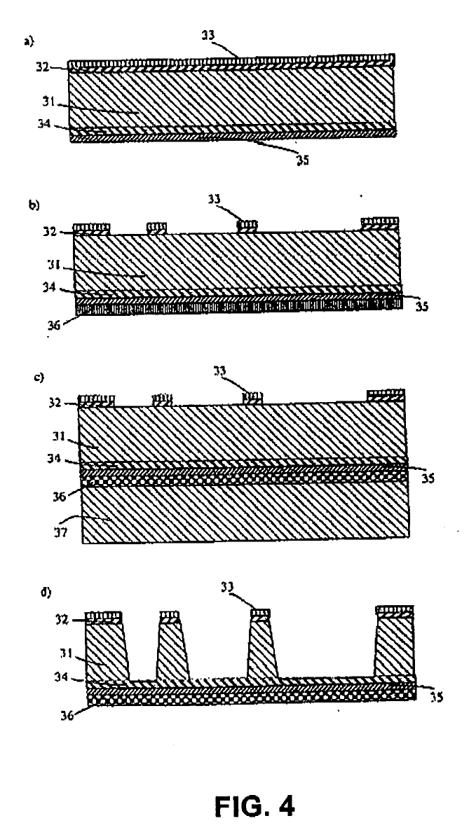

Furthermore a method (FIG. 4) is disclosed for fabricating rubber membranes which can be used with devices according to embodiments of the present invention. This method comprises the following steps:

On a first side of a substrate 31 a silicon oxide/silicon nitride stack 32, 33 is deposited (FIG. 4, step a)) which will serve as an etch mask to define the membrane pattern. The oxide layer 32 has a thickness of 470 nm, while the thickness of the nitride layer 33 is 150 nm. Other materials and/or other thickness and/or another number of layers may be used to serve as an etch mask. When using an oxide/nitride stack 32, 33, preferably the ratio of the thickness of the oxide and the nitride layer 32, 33 is about three to balance out the tensile and compressive forces. The substrate 31 can be a semiconductor wafer or slice; e.g., a silicon wafer, or an insulating slice, e.g., a glass slice. Particularly, a six inch p-type (100) oriented monocrystalline silicon wafer may be used.

On the second side of the substrate 31 a silicon oxide/silicon nitride stack 34, 35 is deposited which will serve as an etch stop to define the membrane pattern. The oxide layer 34 has a thickness of 470 nm while the thickness of the nitride layer 35 is 150 nm. Other, preferably insulating materials and/or other thickness and/or another number of layers may be used to serve as an etch stop. When using an oxide/nitride stack 34, 35, preferably the ratio of the thickness of the oxide and the nitride layer 34, 35 is about three to balance out the tensile and compressive forces. One can also choose to omit this etch stop dependent on the etch procedure.

The oxide/nitride stack 32, 33 on the first side of the substrate 31 is patterned (FIG. 4, step b)) by means of a sequence of photolithographic steps and wet and/or dry etching steps.

The second side of the substrate 31 is coated with liquid rubber, i.e., ELASTOSIL LR3003/10A, B (Wacker Chemie) 36. The relatively low viscosity of the rubber allows for a spin-coating technique. By varying the speed and the time of spinning, the thickness of the layer 36 can be adjusted ranging from 5 to 50 μm. For larger thickness, a multilayer structure can be fabricated by spinning different layers on top of each other. A spin rate of 3000 rpm and a spin time of 60 seconds renders a layer thickness of about 70 μm. The surface of the substrate 31 is chemically modified to make it water repellent by treating the surface with hexamethyidisiloxane (HMDS). The viscosity of the rubber, and thus the layer thickness, can be reduced by adding small amounts of silicone oil.

A second substrate 37, particularly a second 6 inch wafer is bonded (FIG. 4, step c)) onto the first by means of the unvulcanised rubber. The bonding is performed in low vacuum to avoid air bubble formation at the substrate-rubber interface. To cure the rubber, the structure is baked for 3 minutes at 170° C. on a hot plate. Alternatively, instead of a second wafer a glass plate may be used. A first side of this glass plate may comprise a wax layer to protect the rubber layer of the first substrate because the first side is exposed to the rubber during the bonding press.

To form the membrane a chemical back etch (FIG. 4, step d)) may be performed in 35 w % KOH at 60° C. The last 10 μm of silicon is etched at room temperature to minimize the risk of breaking the oxide/nitride layer underneath. The rubber type used is not attacked by KOH at room temperature so the second sacrificial substrate 37 needs no etch stop. If the bottom oxide/nitride layer 34, 35 of the first substrate 31 is not a structural element of the design, it may be omitted from the beginning, making the rubber layer 36 an etch stop for both etching sides. The oxide/nitride stack 34, 35 may be necessary in cases where, e.g., gas impermeability is needed (the rubber is permeable for gasses) or chemicals need to be transported which attack the rubber. In case a waxed glass plate is used instead of a silicon wafer, the second side of the plate is etched in KOH at 40° C. The wax is removed by 1,1,1-trichloroethane.

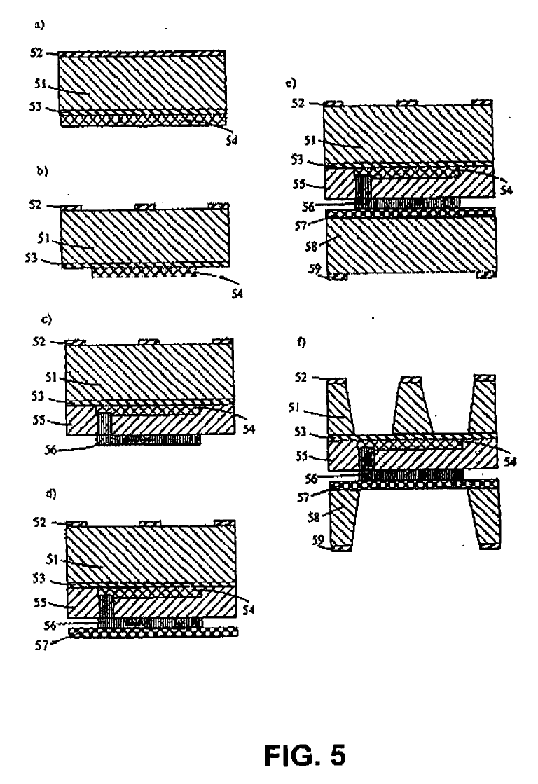

Furthermore, a method is disclosed for fabricating a device used to monitor chemical and physical processes which are accompanied by changes in heat content or enthalpy, which device may be used in embodiments of the present invention. The device can be capable of handling a very small amount of a substance. These requirements can be achieved by micromachining, a technique closely related to integrated circuit fabrication technology. The starting material is a substrate, e.g., a semiconductor wafer or slice, particularly a monocrystalline silicon wafer, or a slice or plate of an insulating material, e.g. a glass slice. Particularly a 150 mm silicon wafer is chosen. This method or process comprises the following steps (FIG. 5):

On a first side of a substrate 51 at least one hard mask layer 52 is deposited (FIG. 5, step a)) which will serve as an etch mask for removing at least parts of the substrate 51. An example of the hard mask layer 52 is a multi-layer structure comprising a first layer, e.g., silicon oxide and a second layer, e.g., a silicon nitride. Other materials and/or another number of layers may be chosen dependent on their suitability as an etch mask. When choosing for an oxide/nitride stack, preferably the ratio of the thickness of the oxide and the nitride layer is about three to balance out the tensile and compressive forces. This results in an oxide layer with a thickness which is typically about 450 nm while the thickness of the nitride layer is typically about 150 nm.

On the second side of the substrate 51 at least one insulating layer 53 can be deposited which can serve as an etch stop layer dependent on the etch procedure used and/or as an insulating layer to thermally and electrically isolate a thermopile and/or to inhibit a direct contact between a substance and the thermopile 2. An example of the insulating layer 53 is a multi-layer structure comprising a first layer, e.g., a silicon oxide layer and a second layer, e.g., a silicon nitride layer. Other insulating materials and/or another number of layers may be chosen dependent on their suitability as an etch stop. When choosing for an oxide/nitride stack, preferably the ratio of the thickness of the oxide and the nitride layer is about three to balance out the tensile and compressive forces. This results in an oxide layer with a thickness which is typically about 450 nm while the thickness of the nitride layer is typically about 150 nm. One can also choose to omit at least a part of this multi-layer structure when its only function is to provide an etch stop, dependent on the etch procedure used.

On the second side of the substrate 51 also a first conductive layer 54 with a thickness typically in the range from 0.3 μm to 1 μm is deposited. The choice of the conductive layer 54 is based on several parameters as there are the magnitude of its Seebeck coefficient, the electrical resistivity, its availability and the compatibility with standard processing steps as used in the manufacturing of integrated circuits. An increase in Seebeck coefficient corresponds with an increase in sensitivity while a lower resistivity corresponds with a lower noise level and thus an improved signal to noise ratio. The resistance of the conductive layer 54 is of course not only determined by its resistivity but also its dimensions which is at least partly a design issue. An example of such a conductive layer 54 is a doped polysilicon layer. In case a polysilicon layer is chosen, the layer may be doped after deposition.

On the first side of the substrate 51 the nitride/oxide stack 52 is patterned (FIG. 5, step b)) in order to define the etch windows for etching away the underlying silicon in order to expose at least parts of the underlying thermopile or the etch stop multi-layer structure on the thermopile 2. This can be done to form channel regions 3, 4 in the vicinity of the thermopile junctions 11, 12. These channel regions 3, 4 can be used to bring a test or reference substance in contact or in the vicinity of the junctions 11, 12 of the thermopile 2. Alternatively, in stead of etching channel regions, one can also choose to expose the underlying thermopile 2 or the etch stop multi-layer structure on the thermopile 2 as a whole. The foil 10 with channels 3, 4 is then placed onto the substrate as in FIG. 8.

On the second side of the substrate 51 the first conductive layer 54, e.g., a doped polysilicon layer is patterned to thereby form the first material 13 of the thermopile 2, i.e., a set of thermocouples which are preferably connected in parallel thermally and in series electrically.

On the second side of the substrate 51 an insulating layer 55 is deposited (FIG. 5, step c)) with a thickness in the range typically from 0.2 μm to 1 μm or from 0.5 μm to 5 μm. The insulating layer 55 is used as an inter-conductive layer dielectric and isolates the different fingers of the polysilicon pattern from each other. The insulating layer 55 is patterned to thereby form via holes through which the underlying first conductive layer 54 can be contacted in order to form hot junctions 11. Examples of such insulating layers 55 are a silicon oxide layer and a benzocyclobutene (BCB) layer.

A second conductive layer 56, having a thermoelectric voltage different from the thermoelectric voltage of the first conductive layer 54, i.e., an aluminum layer with a thickness of 200 nm, is deposited, e.g., by means of evaporation on the second side of the substrate 51. The second conductive layer 56 is patterned to thereby form the second material 14 of the thermopile 2.

On the second side of the substrate 51 an insulating layer 57 is deposited (FIG. 5, step d)) to serve as a membrane. The membrane should thermally and electrically isolate the thermopile 2 and mechanically support the thermopile 2. Silicon oxide and/or silicon nitride can be used as membrane materials, but preferably a liquid rubber, i.e., ELASTOSIL LR3003/10A, B (Wacker Chemie) is used. The rubber membrane fulfils the stringent biocompatibility requirements necessary for medical applications, allows for relatively large pressures to be build up, e.g., when the test substance is a solution which is pumped through the device, renders the sensor excellent thermal isolation properties, enables the active area to be very large and makes it possible to have optical access thanks to its transparency. The relatively low viscosity of the rubber allows for a spin-coating technique. By varying the speed and the time of spinning, the thickness of the layer can be adjusted ranging from 5 to 50 μm. For larger thickness, a multilayer structure can be fabricated by spinning different layers on top of each other. A spinrate of 3000 rpm and a spintime of 60 seconds renders a layer thickness of about 70 μm. The surface of the substrate 51 is chemically modified to make it water repellent by treating the surface with hexamethyldisiloxane (HMDS). The viscosity of the rubber, and thus the layer thickness, can be further reduced by adding small amounts of silicone oil resulting in layer thickness down to 1 μm.

A second substrate 58, particularly a second 150 mm silicon wafer, is bonded (FIG. 5, step e)) onto the first substrate 51 by means of the unvulcanised rubber. The bonding is performed in low vacuum to avoid air bubble formation at the substrate-rubber interface. To cure the rubber, the structure is baked, e.g. for 3 minutes at 170° C. on a hot plate. Alternatively, instead of a second wafer a glass plate is used. A first side of this glass plate comprises a wax layer to protect the rubber layer of the first substrate because the first side is exposed to the rubber during the bonding process.

To expose the thermopile 2 and the membrane, a chemical back etch is performed (FIG. 5, step f), e.g. in 35 w % KOH at 60° C. The last 10 μm of silicon is etched at room temperature to minimize the risk of breaking the oxide/nitride layer on the thermopile 2. The rubber type used is not attacked by KOH at room temperature so the second sacrificial substrate needs no etch stop. In case a waxed glass plate is used instead of a silicon wafer, the second side of the plate is etched in KOH at 40° C. The wax is removed by 1,1,1-trichloroethane. Alternatively an etch mask (59), e.g., a silicon oxide/silicon nitride stack, can be deposited and patterned on the free surface of the second substrate. By doing so, during the back etch, e.g., only the glass or silicon underneath the thermopile is removed to thereby free the membrane.

Alternatively, instead of forming a membrane on the thermopile 2 one can also choose to fix a substrate, e.g., a glass plate or a polyvinylchloride plate, directly on the thermopile. The substrate will isolate and mechanically support the thermopile.

While the above description has pointed out novel features of the invention as applied to various embodiments, the skilled person will understand that various omissions, substitutions, and changes in the form and details of the device or process illustrated may be made without departing from the scope of the invention. Therefore, the scope of the invention is defined by the appended claims rather than by the foregoing description. All variations coming within the meaning and range of equivalency of the claims are embraced within their scope.

It is to be understood that although specific constructions and configurations, as well as materials, have been discussed herein for devices according to the present invention, deviations can be made therein without departing from the spirit and scope of the present invention.

While the invention has been shown and described with reference to preferred embodiments, it will be understood by those skilled in the art that various changes or modifications in form and detail may be made without departing from the scope and spirit of this invention.

1-14. (canceled)

15. An instrument for monitoring processes which are accompanied by changes in heat content or enthalpy, the instrument comprising:
a support having a first surface and a second surface;
at least one pair of thermally sensitive devices, wherein one device is located in a first region of the first surface of the support and the other device is located in a second region of the first surface of the support, wherein the first region is thermally and electrically isolated from the second region, and wherein each thermally sensitive device generates an electrical output signal in response to a thermal input; and
a replaceable substrate comprising a first channel for bringing a first substance in thermal contact with the first region; and a second channel for bringing a second substance in thermal contact with the second region,
wherein the replaceable substrate is formed of a polymeric foil.

16. An instrument according to claim 15, wherein the polymeric foil comprises a 3D pattern.

17. An instrument according to claim 15, wherein the polymeric foil is made from TOPAS® Thermoplastic Olefin Polymer of Amorphous Structure.

18. An instrument according to claim 15, further comprising an amount of thermally conductive material present at a side of the replaceable substrate facing the at least one pair of devices.

19. An instrument according to claim 18, wherein the first and second channels have a bottom which comprises a reservoir for being provided with a drop of thermally conductive material.

20. An instrument according to claim 18, wherein the amount of thermally conductive material is between 10 nl and 10 μl.

21. An instrument according to claim 15, wherein the replaceable substrate comprises a side facing the at least one pair of devices, and wherein the side of the replaceable substrate is chemically modified so as to be hydrophilic.

22. An instrument according to claim 15, further comprising a take-up roll and a dispensing roll for providing a continuous system of providing and removing parts of replaceable substrate.

23. An instrument according to claim 15, wherein the replaceable substrate comprises a surface that, in use, is in contact with a sample to be measured, and wherein the surface of the replaceable substrate is modified so as to provide pre-determined binding characteristics.

24. An instrument according to claim 15, wherein a hydrostatic or electrostatic attraction exists between the replaceable substrate and another part of the instrument on which the replaceable substrate is provided.

25. An instrument according to claim 15, wherein the first region is isolated from the second region by the support.

26. Use of the instrument according to claim 15 in calorimetric screening.

27. Use of the instrument according to claim 15 in analysis of activity of biological cells.
